(19) United States
(12) Patent Application Publication
(10) Pub. No.: US 2016/0284917 A1
(43) Pub. Date: Sep. 29, 2016

(54) Passivation Layer for Solar Cells

(71) Applicants: Seung Bum Rim, Palo Alto, CA (US); David D. Smith, Campbell, CA (US); Michael C. Johnson, Alameda, CA (US); Christine Bourdet Simmons, San Jose, CA (US)

(72) Inventors: Seung Bum Rim, Palo Alto, CA (US); David D. Smith, Campbell, CA (US); Michael C. Johnson, Alameda, CA (US); Christine Bourdet Simmons, San Jose, CA (US)

(21) Appl. No.: 14/672,072

(22) Filed: Mar. 27, 2015

(51) Int. Cl. H01L 31/075; H01L 31/0216; H01L 31/077; H01L 31/0376; H01L 31/0224

(52) U.S. Cl. CPC H01L 31/075; H01L 31/03762; H01L 31/022458; H01L 31/077; H01L 31/02167

(57) ABSTRACT

Methods of fabricating solar cells having passivation layers, and the resulting solar cells, are described. In an example, a solar cell includes a substrate having a first surface and a second surface. A plurality of emitter regions is disposed on the first surface of the substrate and spaced apart from one another. An amorphous silicon passivation layer is disposed on each of the plurality of emitter regions and between each of the plurality of emitter regions, directly on an exposed portion of the first surface of the substrate.

### TECHNICAL FIELD

Embodiments of the present disclosure are in the field of renewable energy and, in particular, methods of fabricating solar cells having passivation layers, and the resulting solar cells.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

Efficiency is an important characteristic of a solar cell as it is directly related to the capability of the solar cell to generate power. Likewise, efficiency in producing solar cells is directly related to the cost effectiveness of such solar cells. Accordingly, techniques for increasing the efficiency of solar cells, or techniques for increasing the efficiency in the manufacture of solar cells, are generally desirable. Some embodiments of the present disclosure allow for increased solar cell manufacture efficiency by providing novel processes for fabricating solar cell structures. Some embodiments of the present disclosure allow for increased solar cell efficiency by providing novel solar cell structures.

### BRIEF DESCRIPTION OF THE DRAWINGS

FIGS. 1A-1D illustrate cross-sectional views of various stages in the fabrication of a solar cell, in accordance with an embodiment of the present disclosure, wherein:

FIG. 1A illustrates a cross-sectional view of a stage in solar cell fabrication involving forming a plurality of emitter regions on a first surface of a substrate;

FIG. 1B illustrates a cross-sectional view of the structure of FIG. 1A following forming an amorphous silicon passivation layer over each of the plurality of emitter regions and between each of the plurality of emitter regions;

FIG. 1C illustrates a cross-sectional view of the structure of FIG. 1B following forming a silicon nitride layer on the amorphous silicon passivation layer; and

FIG. 1D illustrates a cross-sectional view of the structure of FIG. 1C following forming a plurality of conductive contacts to the plurality of emitter regions.

FIGS. 2A-2B illustrate cross-sectional views of various stages in the fabrication of a solar cell, in accordance with another embodiment of the present disclosure, wherein:

FIG. 2A illustrates a cross-sectional view of a stage in solar cell fabrication involving forming a plurality of emitter regions on a first surface of a substrate and forming a dielectric layer on each of the plurality of emitter regions and between each of the plurality of emitter regions; and

FIG. 2B illustrates a cross-sectional view of the structure of FIG. 2A following forming a plurality of conductive contacts to the plurality of emitter regions.

FIG. 3 is a flowchart listing operations in a method of fabricating a solar cell as corresponding to FIGS. 1A-1D or 2A-2B, in accordance with an embodiment of the present disclosure.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

### TERMINOLOGY

The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. §112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” solar cell does not necessarily imply that this solar cell is the first solar cell in a sequence; instead the term “first” is used to differentiate this solar cell from another solar cell (e.g., a “second” solar cell).

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Methods of fabricating solar cells having passivation layers, and the resulting solar cells, are described herein. In the following description, numerous specific details are set forth, such as specific process flow operations, in order to provide a thorough understanding of embodiments of the present disclosure. It will be apparent to one skilled in the art that embodiments of the present disclosure may be practiced without these specific details. In other instances, well-known fabrication techniques, such as lithography and patterning techniques, are not described in detail in order to not unnecessarily obscure embodiments of the present disclosure. Furthermore, it is to be understood that the various embodiments shown in the figures are illustrative representations and are not necessarily drawn to scale.

Disclosed herein are solar cells. In one embodiment, a solar cell includes a substrate having a first surface and a second surface. A plurality of emitter regions is disposed on the first surface of the substrate and spaced apart from one another. An amorphous silicon passivation layer is disposed on each of the plurality of emitter regions and between each of the plurality of emitter regions, directly on an exposed portion of the first surface of the substrate.

In another embodiment, a solar cell includes a substrate having a first surface and a second surface. A plurality of emitter regions is disposed on the first surface of the substrate and spaced apart from one another. A dielectric layer is disposed on each of the plurality of emitter regions and between each of the plurality of emitter regions, directly on an exposed portion of the first surface of the substrate. An amorphous silicon passivation layer is disposed on the dielectric layer.

Also disclosed herein are methods of fabricating solar cells. In one embodiment, a method of fabricating a solar cell involves forming a plurality of emitter regions on a first surface of a substrate, each of the plurality of emitter regions spaced apart from one another. The method also involves forming an amorphous silicon passivation layer over each of the plurality of emitter regions and between each of the plurality of emitter regions.

One or more embodiments described herein are directed to methods of fabricating solar cells with multilayer passivation of polysilicon emitters of the solar cells. In one such embodiment, the passivation of a polysilicon/tunnel oxide/Si interface is improved by using an amorphous silicon (a-Si) or a-Si and silicon nitride (SiN) layer structure formed on top of polysilicon emitter regions. The passivation layers or passivation layer stacks described herein may be fabricated without the use of new tooling or manufacturing arrangements.

To provide context, a polysilicon/tunnel oxide/Si interface provides for very low saturation current density (Jo) to enable solar cells to exhibit high efficiency. However, options for achieving a low Jo have been limited thus far. For example, the use of new tunnel oxide materials such as a nitride oxide or the use of nitridation has been employed to suppress out-diffusion. However, the use of such materials and processes often require expensive new processing or new tool development, and the method may be limited to use of boron-doped polycrystalline silicon emitter regions. In a particular example, P-poly Jo has been limited at 6 fA/cm² with state of the art processing, while N-poly Jo is close to 1 fA/cm². P-poly Jo reduction will result in efficiency improvement, but such reduction has not been achievable to date.

Addressing one or more of the above issues, in an embodiment, passivation of a polysilicon emitter is enhanced by implementing a multilayer structure deposited thereon. In one such embodiment, an a-Si layer is included in a bottom anti-reflective coating (BARC) stack to improve passivation quality of polysilicon emitter regions below the stack.

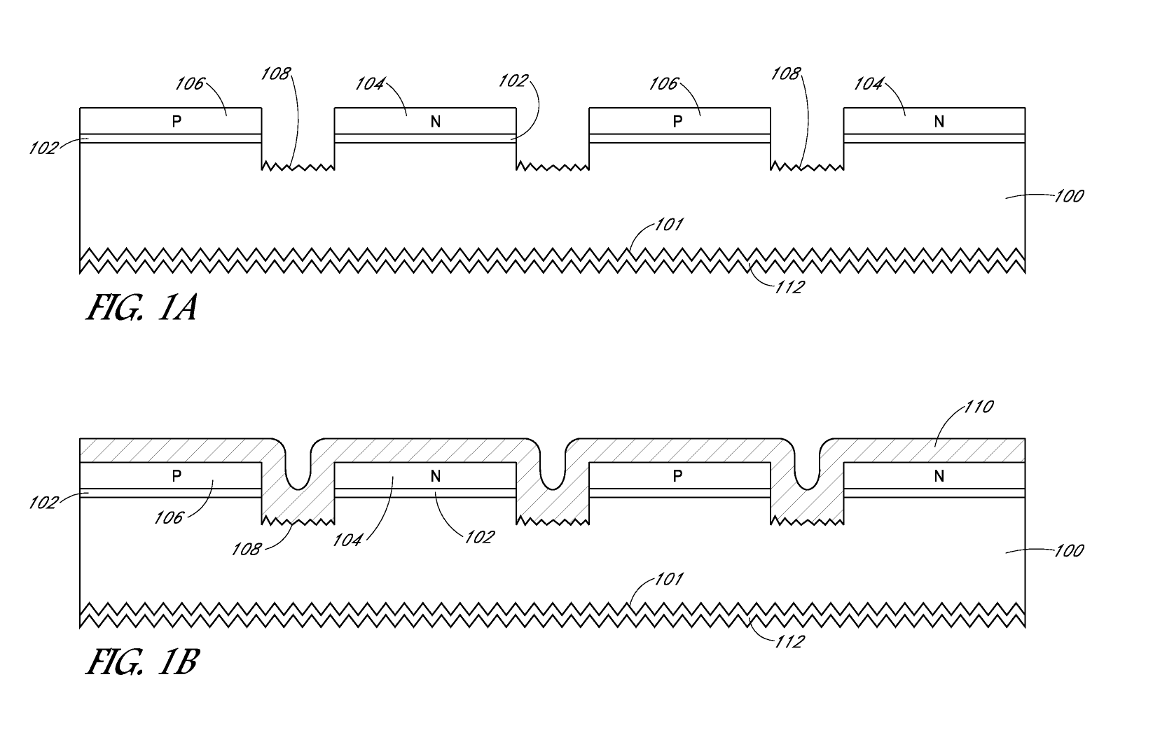

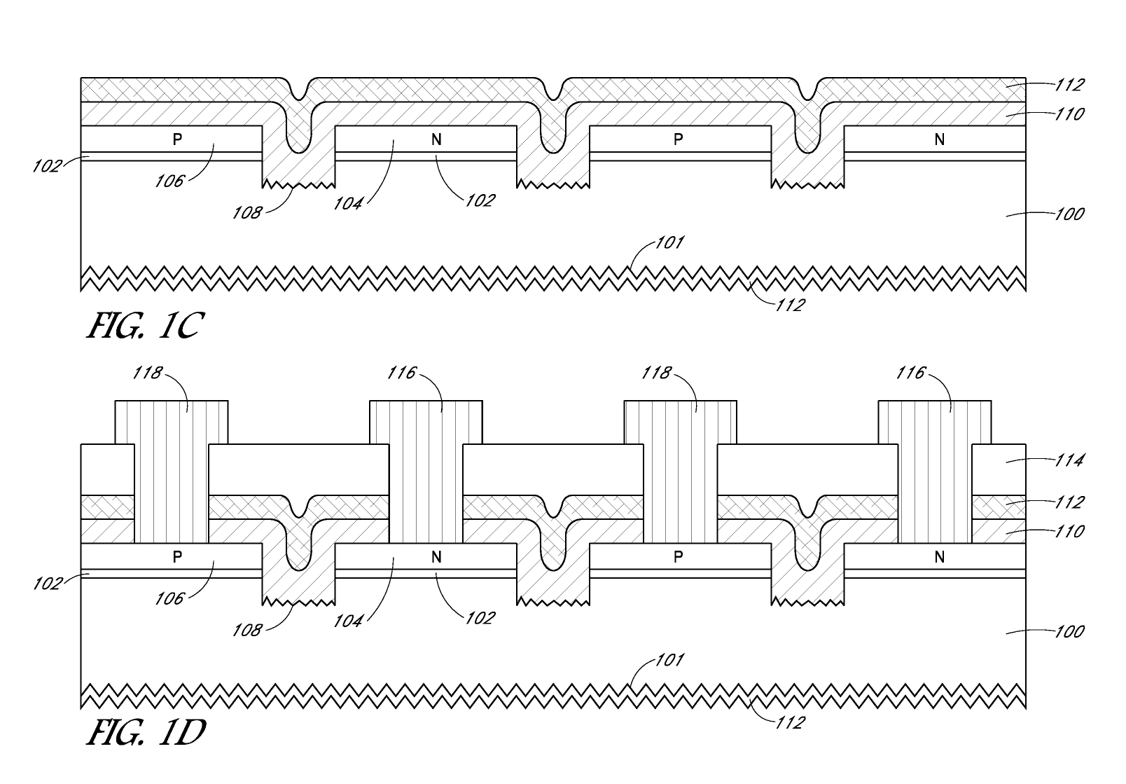

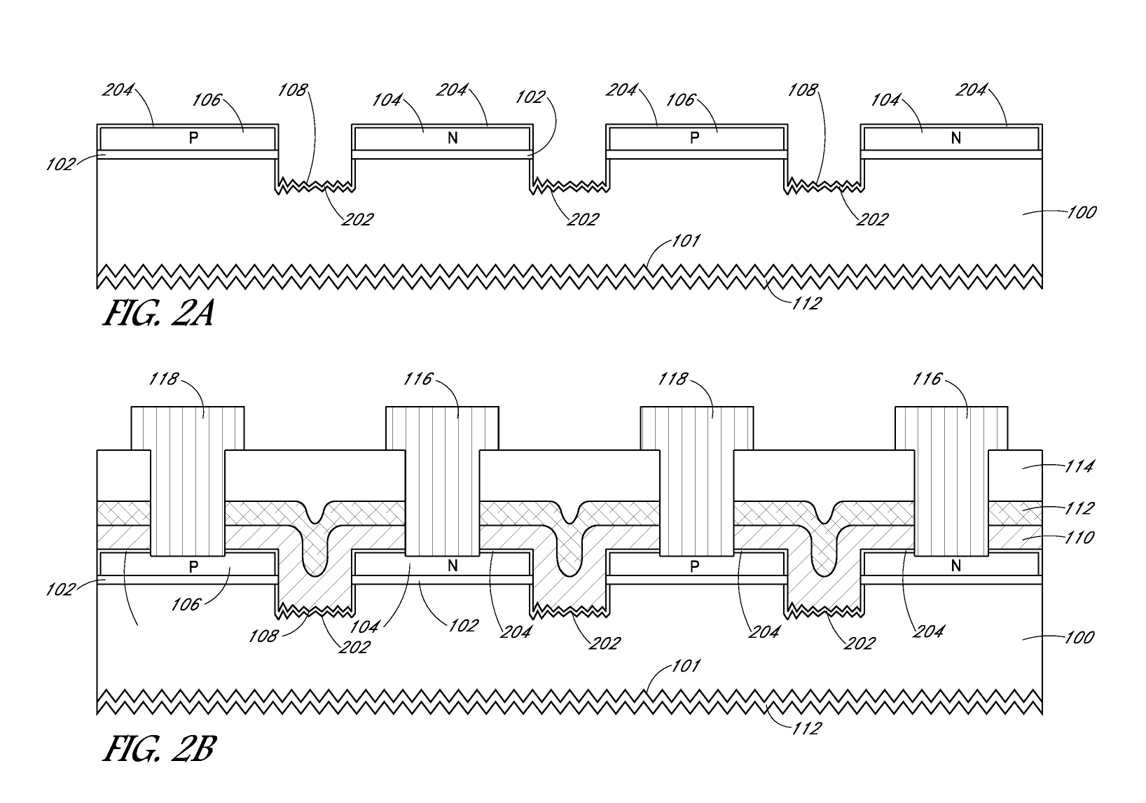

In an exemplary process flow, FIGS. 1A-1D illustrate cross-sectional views of various stages in the fabrication of a solar cell, in accordance with an embodiment of the present disclosure. FIG. 3 is a flowchart 300 listing operations in a method of fabricating a solar cell as corresponding to FIGS. 1A-1D, in accordance with an embodiment of the present disclosure.

Referring to FIG. 1A and corresponding operation 302 of flowchart 300, a plurality of alternating N-type and P-type semiconductor regions are formed above a substrate. In particular, a substrate 100 has disposed there above N-type semiconductor regions 104 and P-type semiconductor regions 106 disposed on a thin dielectric material 102 as an intervening material between the N-type semiconductor regions 104 or P-type semiconductor regions 106, respectively, and the substrate 100. The substrate 100 has a light-receiving surface 101 opposite a back surface above which the N-type semiconductor regions 104 and P-type semiconductor regions 106 are formed. In an embodiment, as depicted in FIG. 1A, each of the plurality of emitter regions 104 and 106 is spaced apart from one another.

In an embodiment, the substrate 100 is a monocrystalline silicon substrate, such as a bulk single crystalline N-type doped silicon substrate. It is to be appreciated, however, that substrate 100 may be a layer, such as a multi-crystalline silicon layer, disposed on a global solar cell substrate. In an embodiment, the thin dielectric layer 102 is a tunneling silicon oxide layer having a thickness of approximately 2 nanometers or less. In one such embodiment, the term “tunneling dielectric layer” refers to a very thin dielectric layer, through which electrical conduction can be achieved. The conduction may be due to quantum tunneling and/or the presence of small regions of direct physical connection through thin spots in the dielectric layer. In one embodiment, the tunneling dielectric layer is or includes a thin silicon oxide layer.

In an embodiment, the alternating N-type and P-type semiconductor regions 104 and 106, respectively, are polycrystalline silicon regions formed by, e.g., using a plasma-enhanced chemical vapor deposition (PECVD) process. In one such embodiment, the N-type polycrystalline silicon emitter regions 104 are doped with an N-type impurity, such as phosphorus. The P-type polycrystalline silicon emitter regions 106 are doped with a P-type impurity, such as boron. As is depicted in FIG. 1A, the alternating N-type and P-type semiconductor regions 104 and 106 may have trenches 108 formed there between, the trenches 108 extending partially into the substrate 100.

In an embodiment, the light receiving surface 101 is a texturized light-receiving surface, as is depicted in FIG. 1A. In one embodiment, a hydroxide-based wet etchant is employed to texturize the light receiving surface 101 of the substrate 100 and, possibly, the trench 108 surfaces as is also depicted in FIG. 1A. It is to be appreciated that the timing of the texturizing of the light receiving surface may vary. For example, the texturizing may be performed before or after the formation of the thin dielectric layer 102. In an embodiment, a texturized surface may be one which has a regular or an irregular shaped surface for scattering incoming light, decreasing the amount of light reflected off of the light receiving surface 101 of the solar cell. Referring again to FIG. 1A, additional embodiments can include formation of a passivation and/or anti-reflective coating (ARC) layers (shown collectively as layer 112) on the light-receiving surface 101. It is to be appreciated that the timing of the formation of passivation and/or ARC layers may also vary.

Referring to FIG. 1B and corresponding operation 306 of flowchart 300, the method also involves forming an amorphous silicon passivation layer 110 over each of the plurality of emitter regions 104 and 106, and between each of the plurality of emitter regions 104 and 106.

In an embodiment, as is depicted in FIG. 1B, a portion of the amorphous silicon passivation layer 110 is formed directly on an exposed portion 108 of the first surface of the substrate 100. In an embodiment, the amorphous silicon passivation layer 110 is formed by depositing amorphous silicon via plasma-enhanced chemical vapor deposition (PECVD). In one such embodiment, the PECVD process is performed at a temperature below approximately 400 degrees Celsius.

In an embodiment, the amorphous silicon passivation layer 110 is an amorphous intrinsic silicon layer. In one such embodiment, a total composition of the amorphous intrinsic silicon layer has a total hydrogen concentration approximately in the range of 5-30 atomic % of total film composition. In one embodiment, the amorphous intrinsic silicon layer has a thickness approximately in the range of 3-15 nanometers. In an embodiment, either during formation the amorphous silicon passivation layer 110, or at a subsequent processing operation such as during annealing operation 310 described below, the method involves driving hydrogen from the amorphous silicon passivation layer 110 to an interface of the plurality of emitter regions 104 and 106 and the substrate 100.

Referring to FIG. 1C and corresponding optional operation 308 of flowchart 300, the method of fabricating a solar cell involves forming a silicon nitride layer 112 on the amorphous silicon passivation layer 110. The silicon nitride layer may be included to provide at least some level of reflective or light-trapping attributes above the emitter regions 104 and 106. It is to be appreciated that other dielectrics may be suitable in place of silicon nitride. For example, other embodiments may involve the use of silicon oxynitride or silicon oxide for layer 112 described herein.

In an embodiment, referring to optional operation 310 of flowchart 300, the substrate 100 (and, hence, the amorphous silicon passivation layer 110) is thermally annealed. In one such embodiment, the thermal annealing is performed at a temperature approximately in the range of 300-550 degrees Celsius. In an embodiment, the thermal annealing is performed subsequent to forming the silicon nitride layer 112 (if present) on the amorphous silicon passivation layer 110.

Referring to FIG. 1D and corresponding optional operation 312 of flowchart 300, conductive contacts 116 and 118 are fabricated to contact the N-type 104 and P-type 106 doped polycrystalline silicon emitter regions, respectively. In an embodiment, the contacts 116 and 118 are fabricated by first depositing and patterning an insulating layer 114 to have openings and then forming one or more conductive layers in the openings. As is also depicted in FIG. 1D, the contact openings are also formed through the amorphous silicon passivation layer 110 and, if present, the silicon nitride layer 112 in order to expose the N-type 104 and P-type 106 doped polycrystalline silicon emitter regions.

In an embodiment, the conductive contacts 116 and 118 include metal and are formed by a deposition, lithographic, and etch approach or, alternatively, a printing process. In an exemplary embodiment, a metal seed layer is formed on the exposed portions of the P-type emitter regions 106 and on the N-type emitter regions 104. A metal layer is then plated on the metal seed layer to form conductive contacts 116 and 118, respectively, for the P-type emitter regions 106 and the N-type emitter regions 124. In an embodiment, the metal seed layer is an aluminum-based metal seed layer, and the metal layer is a copper layer.

With reference again to FIG. 1D, in a first embodiment, a finalized solar cell includes a substrate 100 having a first surface and a second surface 101. A plurality of emitter regions 104 and 106 is disposed on the first surface of the substrate 100 and spaced apart from one another. An amorphous silicon passivation layer 110 is disposed on each of the plurality of emitter regions 104 and 106, and between each of the plurality of emitter regions 104 and 106. The amorphous silicon passivation layer 110 is disposed directly on an exposed portion 108 of the first surface of the substrate 100.

In an embodiment, the substrate 100 is a lightly doped N-type monocrystalline substrate having a phosphorous doping concentration approximately in the range of 1E14-1E16 atoms/cm³ at the exposed portion 108 of the first surface of the substrate 100. In one such embodiment, the amorphous silicon passivation layer 110 is an amorphous intrinsic silicon layer. In a particular such embodiment, a total composition of the amorphous intrinsic silicon layer has a total hydrogen concentration approximately in the range of 5-30 atomic % of total film composition. In another particular such embodiment, the amorphous intrinsic silicon layer has a thickness approximately in the range of 3-15 nanometers.

Referring again to FIG. 1D, in an embodiment, each of the plurality of emitter regions 104 and 106 is separated from one another by a plurality of trenches 108 disposed in the first surface of the substrate 100. In one such embodiment, the amorphous silicon passivation layer 110 is disposed in the plurality of trenches 108, as is depicted in FIG. 1D. In an embodiment, the solar cell further includes a silicon nitride layer 112 disposed on the amorphous silicon passivation layer 110, as is also depicted in FIG. 1D. In one such embodiment, the silicon nitride layer 112 has a thickness approximately in the range of 30-100 nanometers. In an embodiment, the solar cell further includes a plurality of conductive contacts 116 and 118 electrically connected to corresponding ones of the plurality of emitter regions 104 and 106. The plurality of conductive contacts 116 and 118 is formed through the silicon nitride layer 112 (if present) and the amorphous silicon passivation layer 110, as is depicted in FIG. 1D.

In an embodiment, the solar cell of FIG. 1D is a back contact solar cell, as is depicted in FIG. 1D. Accordingly, the surface 101 is a light-receiving surface of the substrate 100, and the plurality of emitter regions 104 and 106 is a plurality of alternating N-type and P-type polycrystalline silicon emitter regions, each disposed on a thin dielectric layer 102 disposed a back surface of the substrate 100. In another embodiment, not depicted in FIG. 1D, the solar cell is a front contact solar cell having one type (N− or P−) of emitter region on surface 101 of substrate 100, and the other type of emitter region on the opposing surface of substrate 100. In the latter embodiment, a second amorphous silicon passivation layer may be included as a passivation layer such that both types of emitter regions have an accompanying passivation layer on their respective sides of substrate 100.

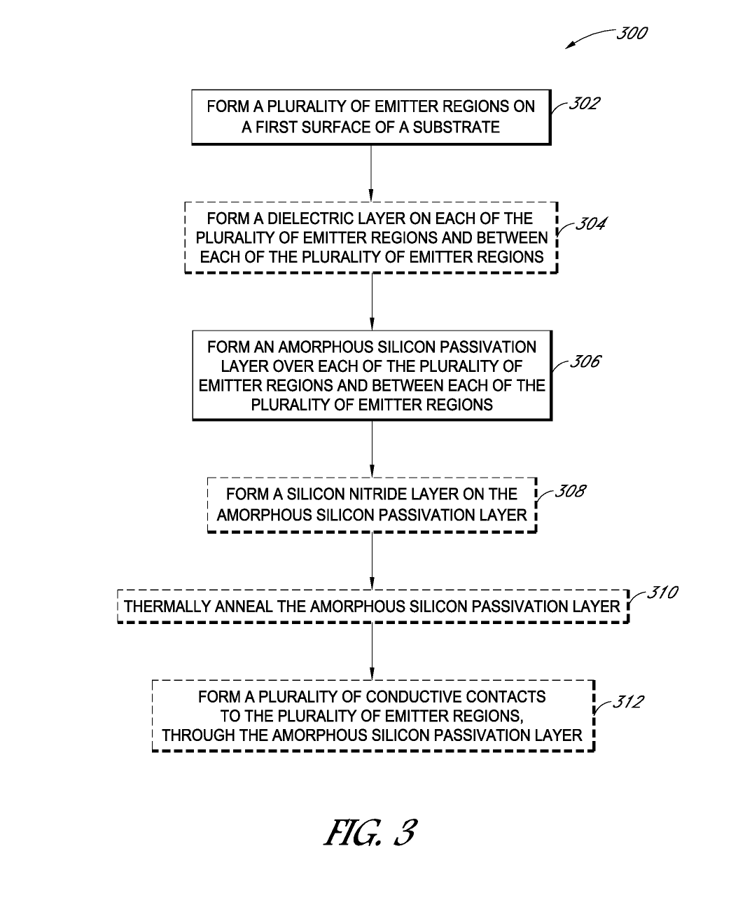

In another exemplary process flow, FIGS. 2A-2B illustrate cross-sectional views of various stages in the fabrication of a solar cell, in accordance with an embodiment of the present disclosure. FIG. 3 is a flowchart 300 listing operations in a method of fabricating a solar cell as corresponding to FIGS. 2A-2B, in accordance with an embodiment of the present disclosure.

Referring to FIG. 2A, using the structure described in association with FIG. 1A as a starting point, and to corresponding operation 304 of flowchart 300, a dielectric layer (202 and 204) is formed on each of the plurality of emitter regions 104 and 106 (see dielectric layer portions 204) and between each of the plurality of emitter regions 104 and 106, directly on an exposed portion 108 of the first surface of the substrate 100 (see dielectric layer portions 202). In an embodiment, one or both of dielectric layer portions 202 and 204 is formed in an oxidation process and is a thin oxide layer. In another embodiment, one or both of dielectric layer portions 202 and 204 is formed in a deposition process and is a thin silicon nitride layer or silicon oxynitride layer.

Referring to FIG. 2B and corresponding operation 306 of flowchart 300, the method also involves forming an amorphous silicon passivation layer 110 over each of the plurality of emitter regions 104 and 106, and between each of the plurality of emitter regions 104 and 106. As depicted in FIG. 2B, in an embodiment, the amorphous silicon passivation layer 110 is formed directly on the dielectric layer (combination of 202 and 204).

In an embodiment, the amorphous silicon passivation layer 110 is formed by depositing amorphous silicon via plasma-enhanced chemical vapor deposition (PECVD). In one such embodiment, the PECVD process is performed at a temperature below approximately 400 degrees Celsius. In an embodiment, the amorphous silicon passivation layer 110 is a layer such as, but not limited to, an amorphous intrinsic silicon layer, an amorphous N-type silicon layer, or an amorphous P-type silicon layer. In one such embodiment, a total composition of the amorphous silicon passivation layer has a total hydrogen concentration approximately in the range of 5-30 atomic % of total film composition. In one embodiment, the amorphous silicon passivation layer 110 has a thickness approximately in the range of 3-15 nanometers. In an embodiment, either during formation the amorphous silicon passivation layer 110, or at a subsequent processing operation such as during annealing operation 310 described below, the method involves driving hydrogen from the amorphous silicon passivation layer 110 to an interface of the plurality of emitter regions 104 and 106 and the substrate 100.

Referring again to FIG. 2B and corresponding optional operation 308 of flowchart 300, the method of fabricating a solar cell involves forming a silicon nitride layer 112 on the amorphous silicon passivation layer 110. The silicon nitride layer may be included to provide at least some level of reflective or light trapping attributes above the emitter regions 104 and 106.

In an embodiment, referring to optional operation 310 of flowchart 300, the substrate 100 (and, hence, the amorphous silicon passivation layer 110) is thermally annealed. In one such embodiment, the thermal annealing is performed at a temperature approximately in the range of 300-550 degrees Celsius. In an embodiment, the thermal annealing is performed subsequent to forming the silicon nitride layer 112 (if present) on the amorphous silicon passivation layer 110.

Referring again to FIG. 2B and corresponding optional operation 312 of flowchart 300, conductive contacts 116 and 118 are fabricated to contact the N-type 104 and P-type 106 doped polycrystalline silicon emitter regions, respectively. In an embodiment, the contacts 116 and 118 are fabricated by first depositing and patterning an insulating layer 114 to have openings and then forming one or more conductive layers in the openings. As is also depicted in FIG. 2B, the contact openings are also formed through the amorphous silicon passivation layer 110 and, if present, the silicon nitride layer 112. Furthermore, the contact openings are also formed through the dielectric layer 204 in order to expose the N-type 104 and P-type 106 doped polycrystalline silicon emitter regions. The conductive contacts of FIG. 2B may be fabricated in a similar manner as described in association with conductive contacts 116 and 118 of FIG. 1D.

With reference again to FIG. 2B, in a second embodiment, a finalized solar cell includes a substrate 100 having a first surface and a second surface 101. A plurality of emitter regions 104 and 106 is disposed on the first surface of the substrate 100 and spaced apart from one another. A dielectric layer (combination of 202 and 204) is disposed on each of the plurality of emitter regions (dielectric layer 204 disposed on each of emitter regions 104 and 106), and between each of the plurality of emitter regions 104 and 106, directly on an exposed portion 108 of the first surface of the substrate 100 (dielectric layer 202 disposed directly on region 108 of substrate 100). An amorphous silicon passivation layer 110 is disposed on the dielectric layer 202/204.

In an embodiment, the substrate 100 is an N-type monocrystalline substrate having a phosphorous doping concentration approximately in the range of 1E18-1E20 atoms/cm³ at the exposed portion 108 of the first surface of the substrate 100. In one such embodiment, the amorphous silicon passivation layer 110 is a layer such as, but not limited to, an amorphous intrinsic silicon layer, an amorphous N-type silicon layer, or an amorphous P-type silicon layer. In a particular such embodiment, a total composition of the amorphous silicon passivation layer 110 has a total hydrogen concentration approximately in the range of 5-30 atomic % of total film composition. In another particular such embodiment, the amorphous silicon passivation layer 110 has a thickness approximately in the range of 3-15 nanometers.

Referring again to FIG. 2B, in an embodiment, each of the plurality of emitter regions 104 and 106 is separated from one another by a plurality of trenches 108 disposed in the first surface of the substrate 100. In one such embodiment, the portion 202 of the dielectric layer and the amorphous silicon passivation layer 110 are disposed in the plurality of trenches 108, as is depicted in FIG. 2B. In an embodiment, the portion 202 of the dielectric layer is composed of silicon dioxide. In an embodiment, the solar cell further includes a silicon nitride layer 112 disposed on the amorphous silicon passivation layer 110, as is also depicted in FIG. 2B. In one such embodiment, the silicon nitride layer 112 has a thickness approximately in the range of 30-100 nanometers. In an embodiment, the solar cell further includes a plurality of conductive contacts 116 and 118 electrically connected to corresponding ones of the plurality of emitter regions 104 and 106. The plurality of conductive contacts 116 and 118 is formed through the silicon nitride layer 112 (if present), through the amorphous silicon passivation layer 110, and through the portions 204 of the dielectric layer, as is depicted in FIG. 2B.

In an embodiment, the solar cell of FIG. 2B is a back contact solar cell, as is depicted in FIG. 2B. Accordingly, the surface 101 is a light-receiving surface of the substrate 100, and the plurality of emitter regions 104 and 106 is a plurality of alternating N-type and P-type polycrystalline silicon emitter regions, each disposed on a thin dielectric layer 102 disposed a back surface of the substrate 100. In another embodiment, not depicted in FIG. 2B, the solar cell is a front contact solar cell having one type (N− or P−) of emitter region on surface 101 of substrate 100, and the other type of emitter region on the opposing surface of substrate 100. In the latter embodiment, a second amorphous silicon passivation layer may be included as a passivation layer such that both types of emitter regions have an accompanying passivation layer on their respective sides of substrate 100.

Although certain materials are described specifically with reference to above described embodiments, some materials may be readily substituted with others with other such embodiments remaining within the spirit and scope of embodiments of the present disclosure. For example, in an embodiment, a different material substrate, such as a group III-V material substrate, can be used instead of a silicon substrate. Additionally, although reference is made significantly to back contact solar cell arrangements, it is to be appreciated that approaches described herein may have application to front contact solar cells as well, examples of which are described briefly above. In other embodiments, the above described approaches can be applicable to manufacturing of other than solar cells. For example, manufacturing of light emitting diode (LEDs) may benefit from approaches described herein. Furthermore, it is to be appreciated that, where N+ and P+ type doping is described specifically, other embodiments contemplated include the opposite conductivity type, e.g., P+ and N+ type doping, respectively.

Thus, methods of fabricating solar cells having passivation layers, and the resulting solar cells, have been disclosed.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

1. A solar cell, comprising:
a substrate having a first surface and a second surface;
a plurality of emitter regions disposed on the first surface of the substrate and spaced apart from one another;
an amorphous silicon passivation layer disposed on each of the plurality of emitter regions and between each of the plurality of emitter regions, directly on an exposed portion of the first surface of the substrate.

2. The solar cell of claim 1, wherein the substrate is a lightly doped N-type monocrystalline substrate having a phosphorous doping concentration approximately in the range of 1E14-1E16 atoms/cm³ at the exposed portion of the first surface of the substrate.

3. The solar cell of claim 2, wherein the amorphous silicon passivation layer is an amorphous intrinsic silicon layer.

4. The solar cell of claim 3, wherein a total composition of the amorphous intrinsic silicon layer has a total hydrogen concentration approximately in the range of 5-30 atomic % of total film composition.

5. The solar cell of claim 3, wherein the amorphous intrinsic silicon layer has a thickness approximately in the range of 3-15 nanometers.

6. The solar cell of claim 1, further comprising:
a silicon nitride layer disposed on the amorphous silicon passivation layer, the silicon nitride layer having a thickness approximately in the range of 30-100 nanometers.

7. The solar cell of claim 6, further comprising:
a plurality of conductive contacts electrically connected to corresponding ones of the plurality of emitter regions, the plurality of conductive contacts formed through the silicon nitride layer and the amorphous silicon passivation layer.

8. The solar cell of claim 1, wherein the solar cell is a back contact solar cell, the first surface is a back surface of the substrate, the second surface is a light-receiving surface of the substrate, and the plurality of emitter regions is a plurality of alternating N-type and P-type polycrystalline silicon emitter regions, each disposed on a thin dielectric layer disposed on the first surface of the substrate.

9. The solar cell of claim 1, wherein the plurality of emitter regions is a plurality of N-type polycrystalline silicon emitter regions, the solar cell further comprising:
a plurality of P-type emitter regions disposed on the second surface of the substrate and spaced apart from one another;
a second amorphous silicon passivation layer disposed over each of the plurality of P-type emitter regions and between each of the plurality of P-type emitter regions, directly on an exposed portion of the second surface of the substrate.

10. The solar cell of claim 1, wherein each of the plurality of emitter regions is separated from one another by a plurality of trenches disposed in the first surface of the substrate, wherein the amorphous silicon passivation layer is disposed in the plurality of trenches.

11. A solar cell, comprising:
a substrate having a first surface and a second surface;
a plurality of emitter regions disposed on the first surface of the substrate and spaced apart from one another;
a dielectric layer disposed on each of the plurality of emitter regions and between each of the plurality of emitter regions, directly on an exposed portion of the first surface of the substrate; and
an amorphous silicon passivation layer disposed on the dielectric layer.

12. The solar cell of claim 11, wherein the substrate is an N-type monocrystalline substrate having a phosphorous doping concentration approximately in the range of 1E18-1E20 atoms/cm³ at the exposed portion of the first surface of the substrate.

13. The solar cell of claim 12, wherein the amorphous silicon passivation layer is a layer selected from the group consisting of an amorphous intrinsic silicon layer, an amorphous N-type silicon layer, and an amorphous P-type silicon layer.

14. The solar cell of claim 13, wherein a total composition of the amorphous silicon passivation layer has a total hydrogen concentration approximately in the range of 5-30 atomic % of total film composition.

15. The solar cell of claim 13, wherein the amorphous silicon passivation layer has a thickness approximately in the range of 3-15 nanometers.

16. The solar cell of claim 11, wherein the dielectric layer comprises a layer of silicon dioxide, the solar cell further comprising:
a silicon nitride layer disposed on the amorphous silicon passivation layer, the silicon nitride layer having a thickness approximately in the range of 30-100 nanometers.

17. The solar cell of claim 16, further comprising:
a plurality of conductive contacts electrically connected to corresponding ones of the plurality of emitter regions, the plurality of conductive contacts formed through the silicon nitride layer, the amorphous silicon passivation layer, and the dielectric layer.

18. The solar cell of claim 11, wherein the solar cell is a back contact solar cell, the first surface is a back surface of the substrate, the second surface is a light-receiving surface of the substrate, and the plurality of emitter regions is a plurality of alternating N-type and P-type polycrystalline silicon emitter regions, each disposed on a thin dielectric layer disposed on the first surface of the substrate.

19. The solar cell of claim 11, wherein the plurality of emitter regions is a plurality of N-type polycrystalline silicon emitter regions, the solar cell further comprising:
a plurality of P-type emitter regions disposed on the second surface of the substrate and spaced apart from one another;
a second dielectric layer disposed on each of the plurality of P-type emitter regions and between each of the plurality of P-type emitter regions, directly on an exposed portion of the second surface of the substrate; and
a second amorphous silicon passivation layer disposed on the second dielectric layer.

20. The solar cell of claim 11, wherein each of the plurality of emitter regions is separated from one another by a plurality of trenches disposed in the first surface of the substrate, wherein the dielectric layer and the amorphous silicon passivation layer are disposed in the plurality of trenches.

21.-29. (canceled)
